(19) United States
(12) Patent Application Publication
(10) Pub. No.: US 2015/0252477 A1
(43) Pub. Date: Sep. 10, 2015

(54) IN-SITU CARBON AND OXIDE DOPING OF ATOMIC LAYER DEPOSITION SILICON NITRIDE FILMS

(71) Applicant: Applied Materials, Inc., Santa Clara, CA (US)

(72) Inventors: Victor NGUYEN, Novato, CA (US); Mihaela BALSEANU, Cupertino, CA (US); Ning LI, San Jose, CA (US); Steven D. MARCUS, San Jose, CA (US); Mark SALY, Santa Clara, CA (US); David THOMPSON, San Jose, CA (US); Li-Qun XIA, Cupertino, CA (US)

(21) Appl. No.: 14/616,206

(22) Filed: Feb. 6, 2015

Related U.S. Application Data
(60) Provisional application No. 61/948,743, filed on Mar. 6, 2014.

(51) Int. Cl. C23C 16/455; C23C 16/458; C23C 16/34; C23C 16/24; C23C 16/50

(52) U.S. Cl. CPC C23C 16/45525; C23C 16/24; C23C 16/50; C23C 16/347; C23C 16/345; C23C 16/458

(57) ABSTRACT

Embodiments disclosed herein generally relate to the processing of substrates, and more particularly, relate to methods for forming a dielectric film. In one embodiment, the method includes placing a plurality of substrates inside a processing chamber and performing a sequence of exposing the substrates to a first reactive gas comprising silicon, and then exposing the substrates to a plasma of a second reactive gas comprising nitrogen and at least one of oxygen or carbon, and repeating the sequence to form the dielectric film comprising silicon carbon nitride or silicon carbon oxynitride on each of the substrates.

### CROSS-REFERENCE TO RELATED APPLICATIONS

This application claims priority to U.S. Provisional Patent Application Ser. No. 61/948,743 (APPM/021194USAL), filed Mar. 6, 2014, which is herein incorporated by reference.

### BACKGROUND

1. Field

Embodiments disclosed herein generally relate to methods for depositing thin films, and more particularly, relate to methods for depositing SiCN or SiCON films using atomic layer deposition.

2. Description of the Related Art

Semiconductor device geometries have dramatically decreased in size since their introduction several decades ago. Modern semiconductor fabrication equipment routinely produce devices with 45 nm, 32 nm and 28 nm feature sizes, and new equipment is being developed and implemented to make devices with dimension of less than 12 nm. In addition, the chip architecture is undergoing an inflection point from 2-dimensional to 3-dimensional structures for better performing, lower power consuming devices. As a result, conformal deposition of materials to form these devices is becoming increasingly important.

Conformal coverage with low pattern loading effect of dielectric films on high aspect ratio structures is needed as device node shrinks down to below 45 nm. Silicon carbon nitride (SiCN) and silicon carbon oxynitride (SiCON) are candidates for spacer and etch-stop layer applications due to their low dielectric constant k. Lower k improves RC capacitor delay, hence improves device performance. In addition, the SiCN SiCON films are more resistant to hydrofluoric acid in peroxide (HF) and buffer oxide etch (BOE) wet clean. However, a high percentage of carbon in the films yields low clean etch rate, but the electrical performance is degraded. On the other hand, high percentage of either oxygen or nitrogen in the films improves electrical performance but low clean etch rate is sacrificed. The conventional process technology is based on reactions in high temperature furnaces. However, furnace processes have very low throughput even with high-volume batch process due to huge amount of pump/purge time. Additionally, controlling process parameters such as gas flows, plasma uniformity are huge disadvantages for the behemoth furnaces.

Therefore, an improved method, both in process controls and cost of ownership, for forming low-k dielectric films is needed.

### SUMMARY

Embodiments disclosed herein generally relate to the processing of substrates, and more particularly, relate to methods for forming a dielectric film. In one embodiment, the method includes placing a plurality of substrates inside a processing chamber and performing a sequence of exposing the substrates to a first reactive gas comprising silicon, and then exposing the substrates to a plasma of a second reactive gas comprising nitrogen and at least one of oxygen or carbon, and repeating the sequence to form the dielectric film comprising silicon carbon nitride or silicon carbon oxynitride on each of the substrates.

In another embodiment, a method for forming a dielectric film is disclosed. The method includes placing a plurality of substrates inside a processing chamber and performing a sequence of exposing the substrates to a first reactive gas comprising silicon; and then exposing the same substrates to a second reactive gas comprising nitrogen and at least one of oxygen or carbon. The sequence is repeated to form the dielectric film comprising silicon carbon nitride or silicon carbon oxynitride on each of the substrates.

In another embodiment, a method for forming a dielectric film is disclosed. The method includes placing a plurality of substrates inside a processing chamber and performing a sequence of exposing the substrates to a first reactive gas comprising silicon and exposing the same substrates to a second reactive gas comprising nitrogen, following by inert or oxygen gas plasma. The sequence is repeated to form the dielectric film comprising silicon carbon nitride or silicon carbon oxynitride on each of the substrates.

### BRIEF DESCRIPTION OF THE DRAWINGS

So that the manner in which the above recited features of the present invention can be understood in detail, a more particular description of the invention, briefly summarized above, may be had by reference to implementations, some of which are illustrated in the appended drawings. It is to be noted, however, that the appended drawings illustrate only typical implementations of this invention and are therefore not to be considered limiting of its scope, for the invention may admit to other equally effective implementations.

FIG. 1 is a cross sectional side view of a processing chamber according to one embodiment.

FIG. 2 is a perspective view of a carousel processing chamber according to one embodiment.

FIG. 3 is a schematic bottom view of a portion of a gas/plasma distribution assembly according to one embodiment.

FIG. 4 illustrates process steps for depositing a dielectric film according to one embodiment.

To facilitate understanding, identical reference numerals have been used, where possible, to designate identical elements that are common to the figures. It is contemplated that elements disclosed in one implementation may be beneficially used on other implementations without specific recitation.

### DETAILED DESCRIPTION

Embodiments disclosed herein generally relate to the processing of substrates, and more particularly, relate to methods for forming a dielectric film. In one embodiment, the method includes placing a plurality of substrates inside a processing chamber and performing a sequence of exposing the substrates to a first reactive gas comprising silicon, and then exposing the substrates to a plasma of a second reactive gas comprising nitrogen and at least one of oxygen or carbon, and repeating the sequence to form the dielectric film comprising silicon carbon nitride or silicon carbon oxynitride on each of the substrates.

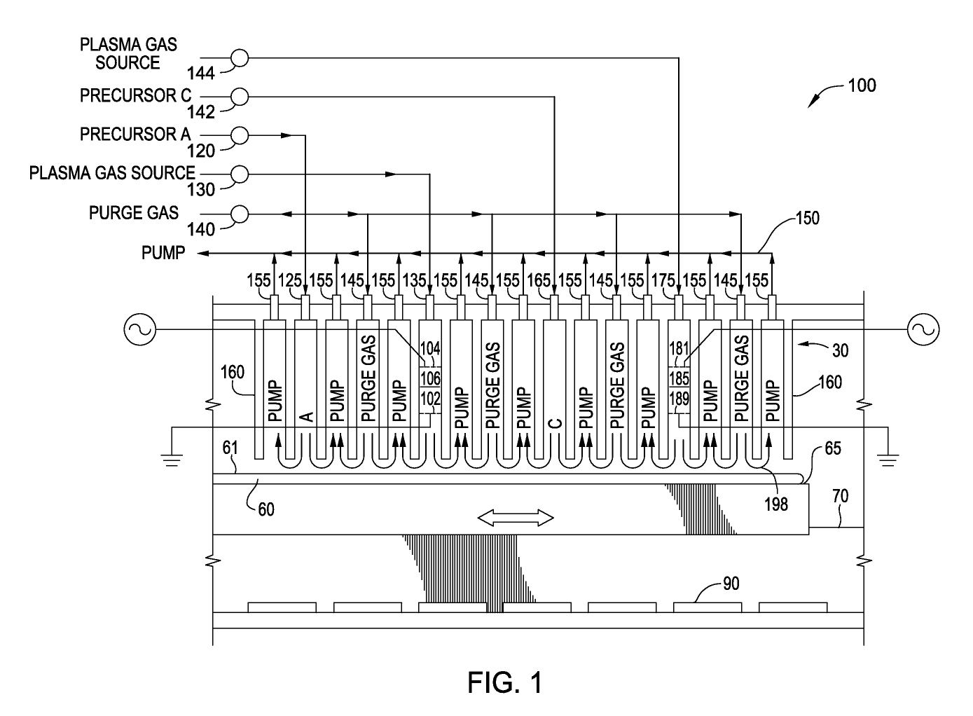

FIG. 1 is a cross sectional side view of a processing chamber 100 according to one embodiment. The processing chamber 100 is capable of performing one or more deposition processes on one or more substrates 60. The processing chamber 100 includes a gas/plasma distribution assembly 30 capable of distributing one or more gases and/or a plasma across the top surface 61 of the substrate 60. The gas/plasma distribution assembly 30 includes a plurality of gas ports to transmit one or more gas streams and/or a plasma to the substrate 60 and a plurality of vacuum ports disposed between adjacent gas ports to transmit the gas streams out of the processing chamber 100. In one embodiment, the gas/plasma distribution assembly includes a first precursor injector 120, a first plasma injector 130, a second precursor injector 142, a second plasma injector 144 and a purge gas injector 140. The injectors 120, 130, 140, 142, 144 may be controlled by a system computer (not shown), such as a mainframe, or by a chamber-specific controller, such as a programmable logic controller. The precursor injector 120 injects a continuous or pulse stream of a reactive precursor of compound A into the processing chamber 100 through a gas port 125. The plasma injector 130 injects a radicalized gas of a reactive precursor of compound B into the processing chamber 100 through a gas port 135. The precursor injector 142 injects a continuous or pulse stream of a reactive precursor of compound C into the processing chamber 100 through a gas port 165. The second plasma source injector 144 injects a plasma of a reactive precursor D or a non-reactive gas, such as argon or nitrogen into the processing chamber 100 through a gas port 175. The precursors A, B, C, D may be used to perform atomic layer deposition (ALD) of SiCN or SiCON on the surface 61 of the substrates 60. In one embodiment, one or more precursors A, B, C, D include a gas mixture having one or more gases.

The precursor A may contain silicon and carbon, precursor B may contain nitrogen and precursor C may contain oxygen and possibly carbon. In the embodiment where three precursors A, B, and C are used, the second plasma source injector 144 injects a plasma of a non-reactive or inert gas, such as argon or nitrogen. In one embodiment, there are only two precursors such as precursors A and B, and the precursor injector 142 injects precursor A and the plasma source injector 144 injects a plasma of the reactive precursor B.

The plasma injector 130 may inject a remote plasma into the processing chamber 100 through plasma/gas port 135. Alternatively, the plasma injector 130 may inject a precursor gas, such as a nitrogen containing gas or a nitrogen, oxygen and carbon containing gas, into plasma region 106 through the plasma/gas port 135, and the electrodes 102, 104 form an electrical field in the plasma region 106 and in turn create a plasma in the plasma region 106. Other type of plasma source may be used instead of electrodes 102, 104 to create a plasma in the plasma region 106. The plasma injector 144 may inject a remote plasma into the processing chamber 100 through plasma/gas port 175. Alternatively, the plasma injector 144 may inject a precursor or inert gas into plasma region 185 through the plasma/gas port 175, and the electrodes 181, 189 form an electrical field in the plasma region 185 and in turn create a plasma in the plasma region 185. Other type of plasma source may be used instead of electrodes 181, 189 to create a plasma in the plasma region 185. The plasma formed in the plasma region 106 may contain the same radicals as the plasma formed in the plasma region 185. Alternatively, the plasma formed in the plasma region 106 may not contain the same radicals as the plasma formed in the plasma region 185. In one embodiment, the electrodes 102, 104 and/or 181, 189 are not present, so precursor gases, instead of a plasma, are flowing across the surface 61 of the substrate 60.

The purge gas injector 140 injects a continuous or pulse stream of a non-reactive gas or purge gas into the processing chamber 100 through a plurality of gas ports 145. The purge gas removes reactive material and reactive by-products from the processing chamber 100. The purge gas is typically an inert gas, such as nitrogen, argon or helium. Gas ports 145 may be disposed between gas ports 125, 135, 165, 175 so as to separate the precursor compounds A, B, C, D; thereby avoiding gas phase cross-reaction between the precursors.

In another aspect, a remote plasma source (not shown) may be connected to the precursor injector 120, precursor injector 130 and precursor injector 142 prior to injecting the precursors into the processing chamber 100. The processing chamber 100 further includes a pumping system 150 connected to the processing chamber 100. The pumping system 150 may be configured to evacuate the gas streams out of the processing chamber 100 through one or more vacuum ports 155. The vacuum ports 155 may be disposed between gas ports 125, 135, 165, 175 so as to evacuate the gas streams out of the processing chamber 100 after the gas streams react with the substrate surface 61 and to further limit cross-contamination between the precursors and the plasma/etchant gas.

The processing chamber 100 includes a plurality of partitions 160 disposed between adjacent ports. A lower portion of each partition 160 extends close to the surface 61 of the substrate 60, for example, about 0.5 mm or greater from the surface 61. In this configuration, the lower portions of the partitions 160 are separated from the substrate surface 61 by a distance sufficient to allow the gas streams to flow around the lower portions toward the vacuum ports 155 after the gas streams react with the substrate surface 61. Arrows 198 indicate the direction of the gas streams. Since the partitions 160 operate as a physical barrier to the gas streams, the partitions 160 also limit gas phase cross-reaction between the precursors. A plurality of heaters 90 may be disposed below the substrate 60 to assist one or more processes performed in the processing chamber 100.

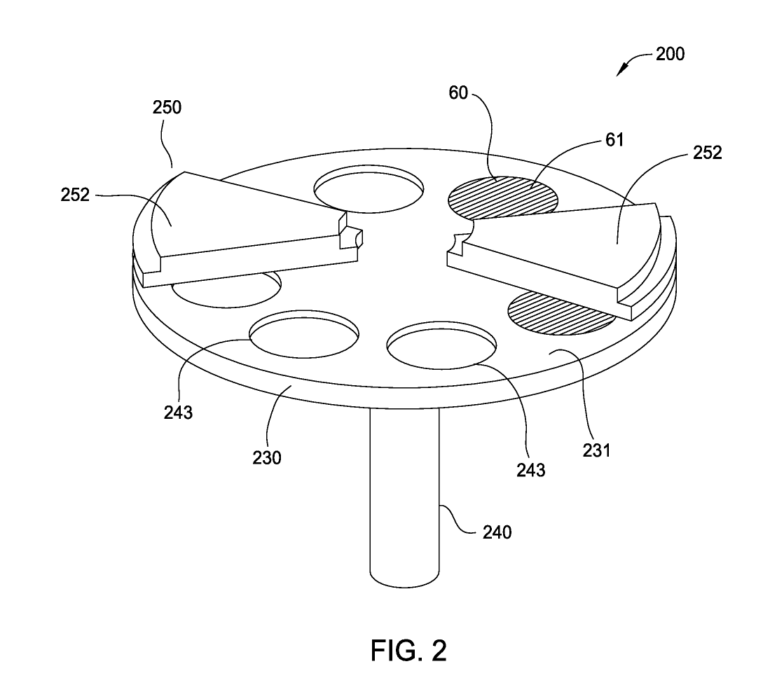

The processing chamber 100 may also include a shuttle 65 and a track 70 for transferring the substrates 60 through the processing chamber 100, passing under the gas/plasma distribution assembly 30. In the embodiment shown in FIG. 1, the shuttle 65 is moved in a linear path through the processing chamber 100. FIG. 2 shows an embodiment in which substrates are moved in a circular path through a carousel processing system.

FIG. 2 is a perspective view of a carousel processing chamber 200 according to one embodiment. The processing chamber 200 may include a susceptor assembly 230 and a gas/plasma distribution assembly 250. The susceptor assembly 230 has a top surface 231 and a plurality of recesses 243 formed in the top surface 231. Each recess 243 may support one substrate 60. In one embodiment, the susceptor assembly 230 has six recesses for supporting six substrates 60. Each recess 243 is sized so that the substrate 60 supported in the recess 243 has the top surface 61 that is substantially coplanar with the top surface 231 of the susceptor assembly 230. The susceptor assembly 230 may be rotated by a support shaft 240 during or between deposition/etching processes.

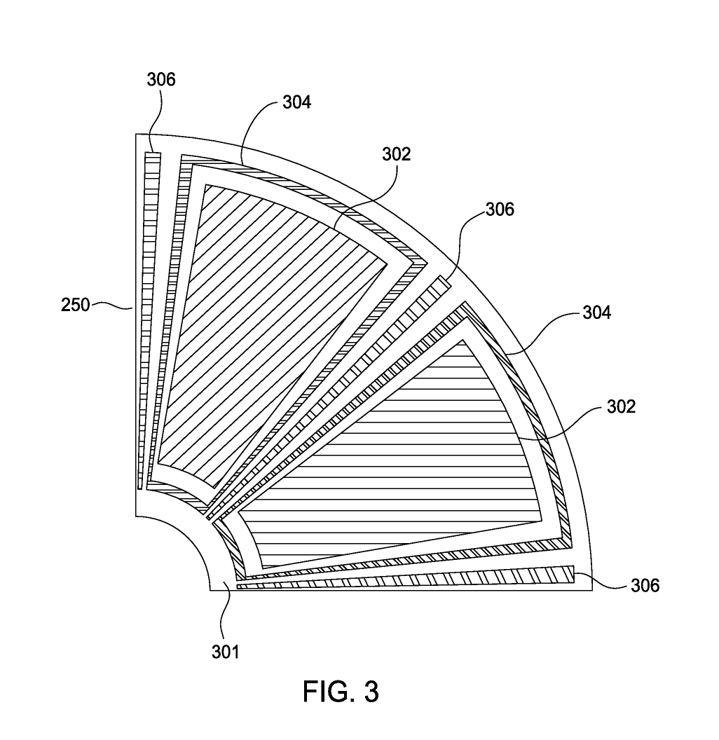

The gas/plasma distribution assembly 250 includes a plurality of pie-shaped segments 252. Portions of the gas/plasma distribution assembly 250 are removed to show the susceptor assembly 230 disposed below, as shown in FIG. 2. Instead of formed by the plurality of segments 252, the gas/plasma distribution assembly 250 may be formed in one piece having the same shape as the susceptor assembly 230. A portion of the gas/plasma distribution assembly 250 is shown in FIG. 3.

FIG. 3 is a schematic bottom view of a portion of the gas/plasma distribution assembly 250. The gas/plasma distribution assembly 250 has a surface 301 facing the susceptor assembly 230. A plurality of gas/plasma ports 302 may be formed in the surface 301. Surrounding each gas/plasma port 302 is a purge gas port 304 and between adjacent gas/plasma ports 302 is a vacuum port 306. The gas/plasma port 302 may have the same function as the gas/plasma port 125, 135, 165, 175, the purge gas port 304 may have the same function as the purge gas port 145, and the vacuum port 306 may have the same function as the vacuum port 155. In one embodiment, there are eight gas/plasma ports 302 disposed in the surface 301. In one embodiment, there are eight segments 252 forming the gas/plasma distribution assembly 250, each having one gas/plasma port 302. The portion of the gas/plasma distribution assembly 250 shown in FIG. 3 may be the combination of two segments 252. In one embodiment, four gas/plasma ports 302 are used for distributing a plasma of a precursor gas and/or an inert gas while the remaining four ports 302 are used for distributing a different precursor gases. After a number of revolutions, a SiCN or a SiCON film is deposited on the surface 61 of the substrates 60.

During operation, the substrates 60 move under these spatially separated ports 302 and get sequential and multiple surface exposures to different chemical or plasma environment to form a SiCN or SiCON film on the surface 61 of the substrates 60. Because the system can accommodate different precursors at different process flows, film properties of the deposited SiCN or SiCON film are well controlled. In one embodiment, the deposited SiCON film has a higher wet clean resistance and lower k value due to high carbon content. In another embodiment, the deposited SiCON film is more stable during subsequent high temperature anneal due to a more balanced nitrogen and oxygen content. In another embodiment, the deposited SiCON film has a highest Si—O content for applications such as a sacrificial etch hard mask.

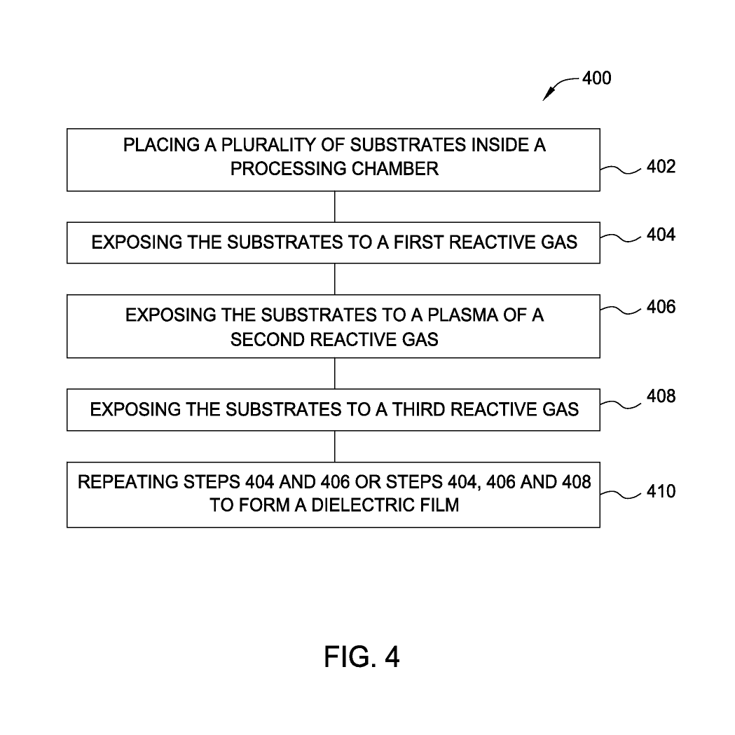

FIG. 4 illustrates process steps 400 for depositing a dielectric film according to one embodiment. At step 402, a plurality of substrates are placed inside a processing chamber, such as processing chamber 100 or processing chamber 200. The substrates are placed on a susceptor assembly, such as the shuttle 65 or the susceptor assembly 230, under a gas/plasma distribution assembly, such as the gas/plasma distribution assembly 30, 230. Each substrate has a surface facing the gas/plasma distribution assembly. At step 404, the substrates are exposed to a first reactive precursor gas, such as the precursor gas A. In one embodiment, the precursor gas A comprises bis(trichlorosilyl)methane (BTCSM), hexachlorodisilane (HCDS), or dichlorosilane (DCS). The precursor gas A may be injected into the processing chamber from a gas port, such as the gas port 125 or 302. The substrates may be rotating under the gas port or may be stationary under the gas port.

Next, at step 406, the substrates are exposed to a plasma of a second reactive gas, such as the precursor gas B. In some embodiments, the second reactive gas is injected into the processing chamber, and the substrates are exposed to the second reactive gas, such as the precursor gas B. The precursor gas B may be injected from an injector, such as the plasma injector 130, into a plasma region, such as the plasma region 106, through a port, such as the port 135. A plasma is formed in the plasma region and is flowed across the top surface of the substrates. The substrates may be rotating under the port or may be stationary under the port. In some embodiments, the precursor gas B comprises one or more nitrogen containing gases, such as acetonitrile, nitrogen, ammonia or combinations thereof, and one or more oxygen containing gases, such as water, oxygen, carbon dioxide, or combinations thereof. In these embodiments, steps 404 and 406 are repeated until a SiCON film is deposited on the surface of the substrates, as shown in step 410.

In other embodiments, the precursor gas B contains a nitrogen containing gas, such as acetonitrile, nitrogen, ammonia or combinations thereof and does not contain any oxygen containing gases. In this case, the substrates are exposed to a third reactive gas, such as the precursor gas C, or a plasma of the third reactive gas, as shown in step 408. The precursor gas C may contain oxygen, such as water, oxygen, carbon dioxide or combinations thereof, or the precursor gas C may contain an inert gas, such as argon. The precursor gas C may be injected from an injector, such as the injector 142, into the processing chamber through a port, such as the port 165. Alternatively, the precursor gas C may be injected from an injector, such as the injector 144, into a plasma region, such as the plasma region 185, through a port, such as the port 175. A plasma is formed in the plasma region and is flowed across the top surface of the substrates. The substrates may be rotating under the port or may be stationary under the port. In these embodiments, steps 404, 406, 408 are repeated until a SiCON film is deposited on the surface of the substrates, as shown in step 410.

In one embodiment, the substrates are first exposed to BTCSM, then to a plasma of nitrogen, ammonia or combination thereof, and lastly to either gases or plasma of water, oxygen, carbon dioxide or combinations thereof. The exposures are repeated until a SiCON film is deposited on each substrate. In another embodiment, the substrates are first exposed to BTCSM, then to a plasma of nitrogen, ammonia or combination thereof and water, oxygen, carbon dioxide or combinations thereof. The exposures are repeated until a SiCON film is deposited on each substrate. In another embodiment, the substrates are first exposed to HCDS, then to a plasma of nitrogen, ammonia or combination thereof, and lastly to either gas or plasma of oxygen and carbon dioxide, water and carbon dioxide, or oxygen, carbon dioxide and water. The exposures are repeated until a SiCON film is deposited on each substrate. In another embodiment, the substrates are first exposed to HCDS, then to a plasma of nitrogen, ammonia or combination thereof, carbon dioxide, and water, oxygen, or combinations thereof. The exposures are repeated until a SiCON film is deposited on each substrate. In another embodiment, the substrates are first exposed to DCS, then to acetonitrile and oxygen, water or carbon dioxide, and lastly to an inert plasma, such as argon, helium or nitrogen to form network. The exposures are repeated until a SiCON film is deposited on each substrate. In another embodiment, the substrates are first exposed to DCS, then to a plasma of acetonitrile and water, oxygen, carbon dioxide or combinations thereof. The exposures are repeated until a SiCON film is deposited on each substrate. In another embodiment, the substrates are first exposed to a first precursor gas containing silicon or silicon and carbon, then to a second precursor gas containing nitrogen and at least one of oxygen or carbon. The exposures are repeated until a SiCN or SiCON film is deposited on each substrate. In another embodiment, the substrates are first exposed to a first precursor gas containing silicon, then to a second precursor gas containing acetonitrile, and lastly to a plasma of gas including oxygen. The exposures are repeated until a SiCON film is deposited on each substrate.

While the foregoing is directed to implementations of the present invention, other and further implementations of the invention may be devised without departing from the basic scope thereof, and the scope thereof is determined by the claims that follow.

1. A method for forming a dielectric film, comprising:
placing a plurality of substrates inside a processing chamber;
performing a sequence of:
exposing the substrates to a first reactive gas comprising silicon; and then
exposing the substrates to a plasma of a second reactive gas comprising nitrogen and at least one of oxygen or carbon; and
repeating the sequence to form the dielectric film comprising silicon carbon nitride or silicon carbon oxynitride on each of the substrates.

2. The method of claim 1, wherein the first reactive gas comprises bis(trichlorosilyl)methane, hexachlorodisilane, or dichlorosilane.

3. The method of claim 2, wherein the second reactive gas comprises ammonia and carbon dioxide.

4. The method of claim 1, wherein the substrates of the plurality of substrates are disposed on a susceptor assembly.

5. The method of claim 4, wherein the susceptor assembly includes a plurality of recesses to support the plurality of substrates.

6. The method of claim 5, wherein the plurality of substrates includes six substrates.

7. The method of claim 1, wherein the first reactive gas further comprises carbon.

8. The method of claim 1, wherein the substrates of the plurality of substrates are rotating when exposed to the first reactive gas or the plasma.

9. A method for forming a dielectric film, comprising:
placing a plurality of substrates inside a processing chamber;
performing a sequence of:
exposing the substrates to a first reactive gas comprising silicon; and then
exposing the substrates to a second reactive gas comprising nitrogen and at least one of oxygen or carbon; and
repeating the sequence to form the dielectric film comprising silicon carbon nitride or silicon carbon oxynitride on each of the substrates.

10. The method of claim 9, wherein the first reactive gas comprises bis(trichlorosilyl)methane, hexachlorodisilane, or dichlorosilane.

11. The method of claim 10, wherein the second reactive gas comprises ammonia and carbon dioxide.

12. The method of claim 9, wherein the plurality of substrates are disposed on a susceptor assembly.

13. The method of claim 12, wherein the susceptor assembly includes a plurality of recesses to support the plurality of substrates.

14. The method of claim 13, wherein the plurality of substrates includes six substrates.

15. The method of claim 9, wherein the first reactive gas further comprises carbon.

16. The method of claim 9, wherein the substrates of the plurality of substrates are rotating when exposed to the first reactive gas or the second reactive gas.

17. A method for forming a dielectric film, comprising:
placing a plurality of substrates inside a processing chamber;
performing a sequence of:
exposing the substrates to a first reactive gas comprising silicon; then
exposing the substrates a second reactive gas comprising nitrogen; and then
exposing the substrates to a plasma of a gas comprising oxygen or an inert gas; and
repeating the sequence to form the dielectric film comprising silicon carbon nitride or silicon carbon oxynitride on each of the substrates.

18. The method of claim 17, wherein the plurality of substrates are disposed on a susceptor assembly.

19. The method of claim 18, wherein the susceptor assembly includes a plurality of recesses to support the plurality of substrates.

20. The method of claim 19, wherein the plurality of substrates includes six substrates.
